(19) United States
(12) Patent Application Publication
(10) Pub. No.: US 2003/0203219 A1
(43) Pub. Date: Oct. 30, 2003

(54) Plastic article with a film sputter deposited thereon

(75) Inventors: Chi-Fang Lin, Taipei (TW); Tzu-Jung Tseng, Taipei (TW); Jui-Hsiang Yang, Taipei (TW); Chun-Ching Li, Taipei (TW)

Correspondence Address: Paul D. Greeley, Esq., Ohlandt, Greeley, Ruggiero & Perle, L.L.P., One Landmark Square, 10th Floor, Stamford, CT, 06901-2682, US

(73) Assignee: Everskil Technology Co., Ltd.

(21) Appl. No.: 10/134,135

(22) Filed: Apr. 26, 2002

(51) Int. Cl. B32B 15/04; C23C 14/00

(52) U.S. Cl. 428/457; 204/192.14

(57) ABSTRACT

A plastic article that includes a plastic substrate and a thin film sputter-deposited on a surface of the plastic substrate. The plastic article is produced by a process in which the surface of the plastic substrate is first bombarded with an ionized gas in a vacuum environment to remove contaminants on the surface, to clean the surface, and to expose pores clogged by the contaminants in the surface. Subsequently, a thin film is deposited on the cleaned surface of the substrate by sputter deposition. A light guide plate for a backlighting device, and a housing for an electronic device, such as a cell phone, may be produced via the process.

### BACKGROUND OF THE INVENTION

1. Field of the Invention

The present invention relates to a plastic article having a film sputter deposited thereon, more particularly to the fabrication of an article having a thin film sputtered on a plastic substrate.

2. Description of the Related Art

In general, the surface resistance of polymers is high such that electrical charges are not free to move on the surface, thereby leading to accumulation of electrical charges on the surface. In certain applications, conductivity modifiers, e.g. conductive carbon black and metal powder, are added to the polymers in order to improve conductivity. Anti-static agents are added as well to prevent accumulation of electrical charges. Since polymers can be easily molded into various forms using economically feasible fabrication processes, they have vast applications. When plastic material is used to fabricate insulating components of electrical devices, protection against electromagnetic interference (EMI), radio frequency interference (RFI) and electrostatic discharge (ESD) has become an important consideration. For such purposes, a metal shielding is usually applied to the surface of the insulating components.

Referring to FIG. 1, a conventional liquid crystal display 1 is shown to include a liquid crystal module 11 and a backlighting module 12. The liquid crystal module 11 includes a liquid crystal layer 110 sandwiched between two glass substrates 111, 112. The glass substrates 111, 112 are sandwiched between a pair of polarizing filters 113, 114. The backlighting module 12 includes a prism 121, a diffusing layer 122, a light guide 123, and a reflecting layer 124. In addition, light sources 125, 126 are provided on opposite sides of the light guide 123.

As shown in FIG. 2, in the backlighting module of FIG. 1, about 40-50% of the light radiated by the light source 125 is transmitted to the light guide 123. A large part of the transmitted light is reflected directly to the diffusing layer 122, whereas a small part of the transmitted light is reflected by the reflecting layer 124 for reception by the light guide 123. Thus, light can be homogenized by the diffusing layer 122 and subsequently transmitted through the prism 121 into the liquid crystal module 11 (see FIG. 1), thereby resulting in uniform luminance.

As shown in FIG. 3, a conventional light guide includes a transparent plastic substrate 40 having a dot pattern 401 as light controlling elements formed thereon to ensure uniform luminance. A reflecting layer 41 is attached to the substrate 40 and is disposed over the dot pattern 401. It is noted that the presence of the dot pattern 401 has an adverse effect on the adhesion of the reflecting layer 41 to the substrate 40.

Another conventional backlighting module is illustrated in FIG. 4. The light guide of this module differs from that shown in FIG. 3 in that the dot pattern 401 in the light guide of FIG. 3 is replaced by a line pattern 301 to improve uniformity of luminance. Similar to the backlighting module of FIG. 2, a diffusing layer 32 and a reflective layer 31 are attached to opposite sides of the substrate 30. It is noted that the aforesaid problem of the light guide shown in FIG. 3 remains unresolved.

### SUMMARY OF THE INVENTION

An object of this invention is to provide a light guide plate by forming a light reflective film via a sputter deposition process on a plastic substrate to achieve improved adhesion.

Another object of this invention is to provide a plastic article, such as an insulating component of an electrical device, with a shielding film deposited thereon by sputtering.

According to one aspect of the invention, a plastic article comprises a plastic substrate and a film bonded integrally to a surface of the plastic substrate, the film being formed on the surface via a process which comprises the steps of:

a) bombarding the surface of the plastic substrate with an ionized gas in a vacuum environment to remove contaminants from the surface, to clean the surface and to expose pores clogged by the contaminants in the surface; and

b) providing the film on the surface cleaned in step a) by sputter deposition.

According to another aspect of the invention, a light guide plate for a back-lighting device, comprises a transparent plastic substrate, and a reflective metal film bonded intimately to the plastic substrate, the reflective metal film being formed on the plastic substrate by a process which comprises the steps of:

a) bombarding the surface of the transparent plastic substrate with an ionized gas in a vacuum environment to remove contaminants from the surface, to clean the surface, and to expose pores clogged by the contaminants in the surface; and

b) providing the metal film on the surface cleaned in step a) by sputter deposition.

According to further aspect of the invention, a housing for an electronic device comprises a plastic case and a film bonded intimately to the plastic case, the film being formed on a surface of the plastic case by a process which comprises the steps of;

a) bombarding the surface of the plastic case with an ionized gas in a vacuum environment to remove contaminants from the surface, to clean the surface, and to expose pores clogged by the contaminants in the surface; and

c) providing the film on the surface cleaned in step a) by sputter deposition.

### BRIEF DESCRIPTION OF THE DRAWINGS

The above and other objects, features and advantages of the invention will become clear from the following description of the preferred embodiments with reference to the accompanying drawings:

FIG. 1 is an exploded schematic view showing a conventional liquid crystal display;

FIG. 2 is a schematic view showing a backlighting module of the conventional liquid crystal display of FIG. 1;

FIG. 3 is an enlarged fragmentary sectional view showing a conventional light guide having a metal film formed thereon;

FIG. 4 is an exploded view showing another conventional backlighting module with a reflective layer and a diffusing layer;

FIG. 5 is an enlarged fragmentary sectional view showing a metal film sputtered on the surface of a plastic substrate of a light guide plate in accordance with the present invention;

FIG. 6 is a view similar to FIG. 6, but with a higher magnification scale, showing the connection between the metal film and the plastic substrate;

FIG. 7 is a perspective view of a cell phone having a housing formed according to the present invention; and

FIG. 8 is a sectional view taken along line 8-8 of FIG. 7; and

FIG. 9 is a schematic view showing a mask applied to a transparent plastic substrate during sputter deposition; and

FIG. 10 is the same view as FIG. 8 but with films sputter-deposited on the outer surface of the plastic substrate.

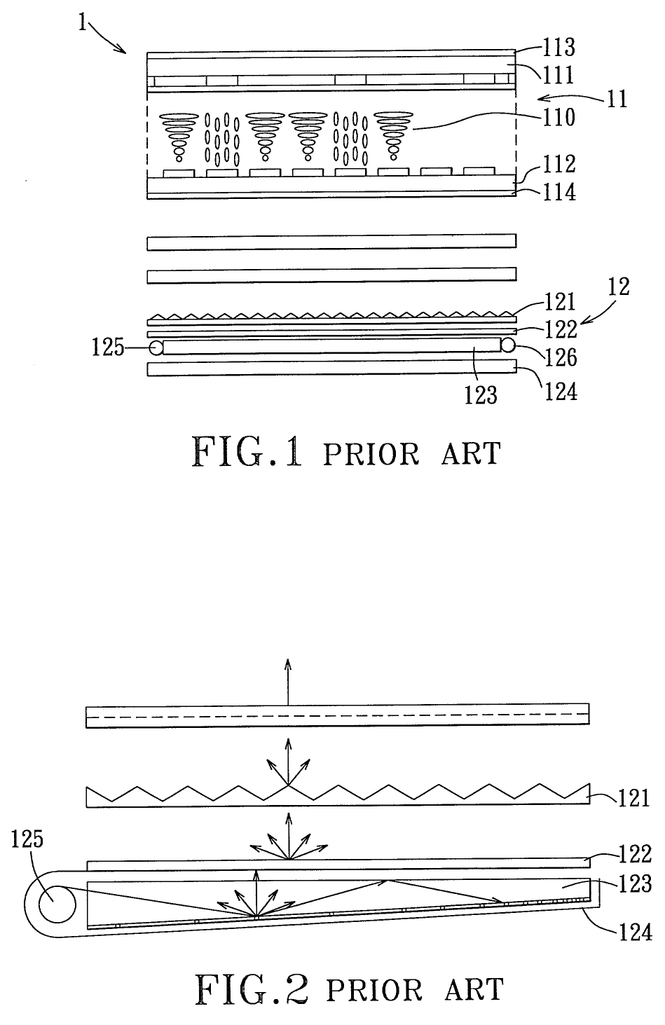

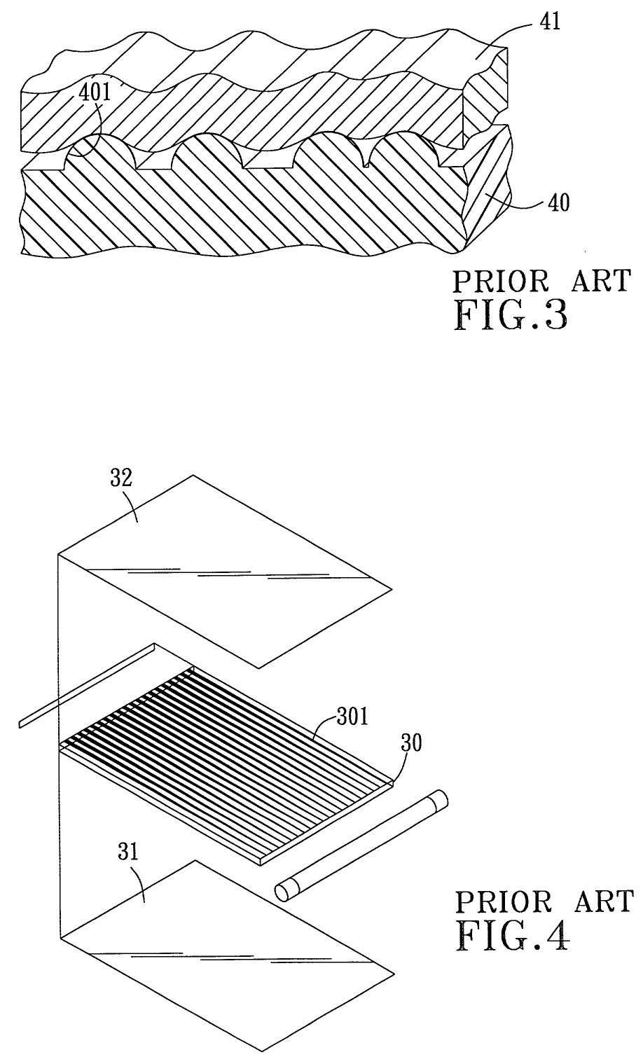

### DETAILED DESCRIPTION OF THE PREFERRED EMBODIMENTS

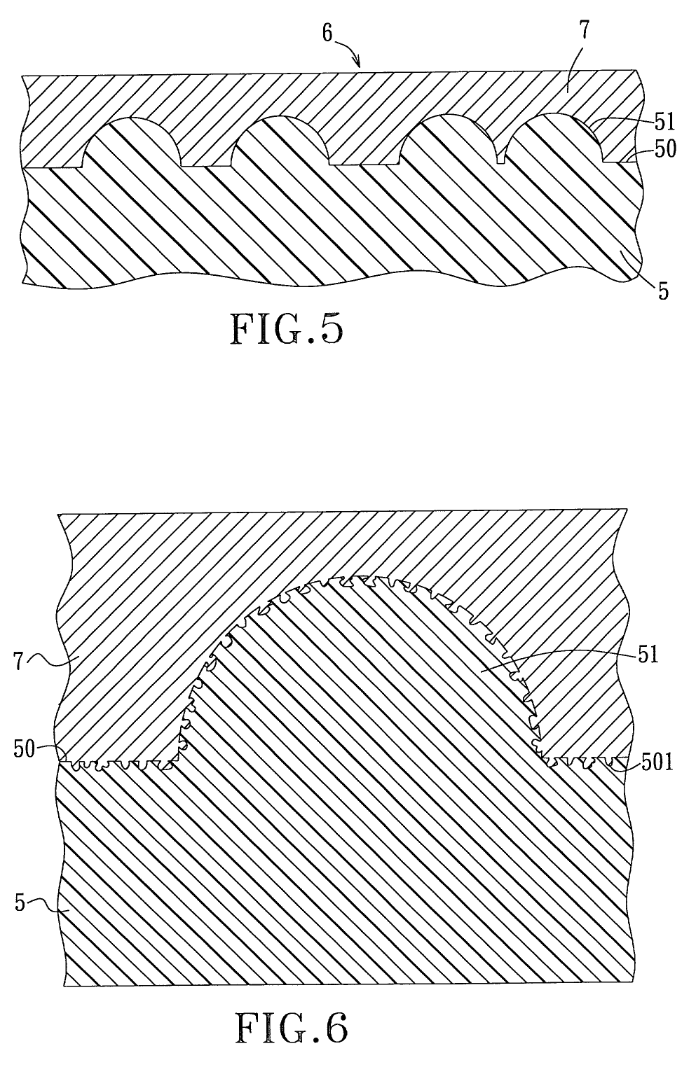

According to the present invention, a plastic article can be formed with a film layer via a sputtering process. A preferred embodiment of the present invention relates to a light guide plate for a back-lighting device. As shown in FIGS. 5 and 6, a light guide plate 6 according to the present invention includes a reflective metal film 7 sputter-deposited on a transparent plastic substrate 5, unlike the conventional light guide plate discussed hereinbefore. The transparent plastic substrate 5 is fabricated by injection molding polyacrylate and has a surface 50 formed with a plurality of protrusions 51. Since contaminants, such as a mold release agent used during the injection molding or the like, usually remain and block pores in the surface 50 of the plastic substrate 5, the surface of the plastic substrate 5 is thoroughly cleaned according to the present invention, prior to forming the reflective metal film 7 on the plastic substrate 5. The cleaning of the plastic substrate 5 is carried out via an etching process in which the surface of the plastic substrate 5 is bombarded by an ionized gas in a vacuum chamber so as to remove contaminants from the plastic substrate 6 and expose pores 501 present in the plastic surface that were clogged by the contaminants. In this cleaning step, argon or a mixture of argon and oxygen is used to produce the ionized gas. The surface 50 of the plastic substrate 5 is roughened due to the pores 501 exposed from the surface 50.

After cleaning, a sputter deposition is carried out to deposit the reflective metal film 7 on the cleaned surface 50 of the plastic substrate 6. Due to the cleaning step, a significant improvement in adhesion of the reflective metal film 7 to the plastic substrate 5 is observed, which can be attributed in part to the roughness of the substrate 5.

The materials suitable for use as a cathode or sputtering target material in this embodiment include aluminum, aluminum alloys, copper, silver alloys and Al₂O₃. The gas used in sputter deposition may be oxygen, nitrogen, or argon, or a mixture thereof. The sputtering temperature is kept to be 50° C.-60° C. The pressures employed in the sputter deposition is preferably 10⁻⁶ torr before the gas is introduced into a sputtering chamber, and preferably 2−3×10⁻³ after the gas is introduced into the sputtering chamber.

During the sputtering, the target material is deposited on the surface 50 of the plastic substrate 5, thus filling the pores 501 and forming the metal film 7 with a predetermined thickness on the surface 50. According to this invention, enhanced adhesion of the metal film 7 to the surface 50 of the plastic substrate 5 is possible, due to the presence of the pores 501 which serve as anchoring sites on the one hand, and might also be attributed to, on the other hand, the physical and/or chemical change in the surface conditions of the plastic substrate 5 upon bombardment with ionized gas with high kinetic energy.

According to this embodiment, the plastic substrate 5 can either be subjected directly to the aforesaid cleaning step, or to a pre-treatment step before undergoing the cleaning step. The pre-treatment step can include washing, drying and other necessary treatments, depending on the manufacturing requirements.

As is well known to a person skilled in this art, optionally, a post-treatment step, such as coating, drying or printing, etc., can be applied to the light guide plate 6 after the sputtering step.

The present invention may be employed to produce a housing for an electronic device, which has a film layer on the surface thereof for decoration and/or other purposes. When the film layer is a conductive metal layer, the film layer can provide electromagnetic shielding effects.

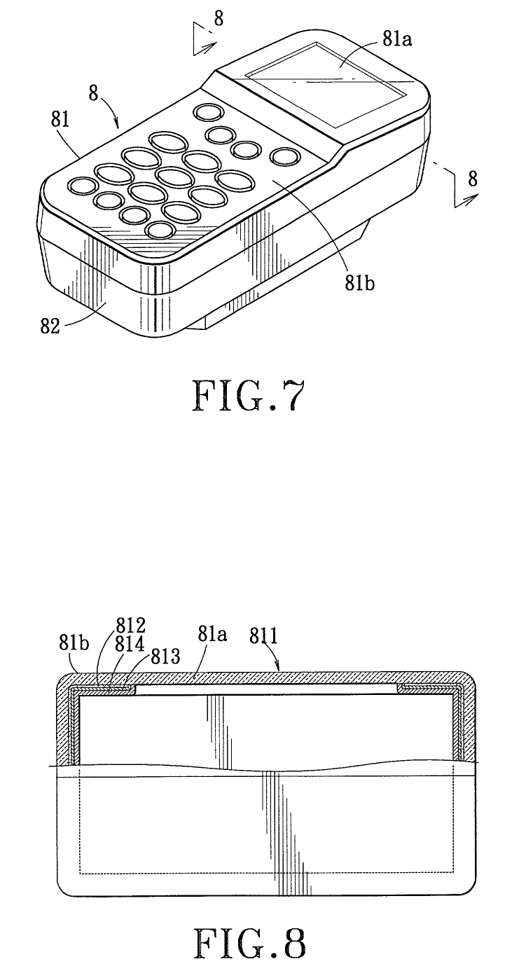

In an embodiment, a process for making a housing for a cell phone is provided. As shown in FIGS. 7 and 8, a housing 8 for a cell phone is comprised of upper and lower plastic cases 81, 82. The upper plastic case 81 has a transparent display part 81a and a non-transparent region 81b both of which are formed from a one-piece transparent plastic substrate 811 made of a transparent plastic material, such as polycarbonate or polyacrylate. The non-transparent region 81b of the upper plastic case 81 has a decorative glossy metal film 812 sputter-deposited on the inner surface of the substrate 811, an adhesive layer 813 applied to the metal film 812, and a conductive metal film 814 sputter-deposited on the adhesive layer 813.

To sputter deposit the metal film 812 on the substrate 811, a cleaning step is conducted to clean the plastic substrate 811 via etching using argon or a mixture of argon and oxygen, like the previous embodiment. A target material used in the sputter deposition may be selected from the group consisting of Al, Cr, Cu, Ti, NiCr, Ni, (Al₂O₃+Pb), (Al₂O₃+Sb) (Al₂O₃+As), TiO₂, Al₂O₃, TiB₂, and SiO₂. The gas used in the sputter deposition step may be oxygen, nitrogen, or argon, or a mixture thereof. The sputtering temperature is kept to be below 50° C. The pressure employed in the sputter deposition is preferably about 10⁻⁶ torr before the gas is introduced into a sputtering chamber, and preferably about 2−3×10⁻³ after the gas is introduced into the sputtering chamber.

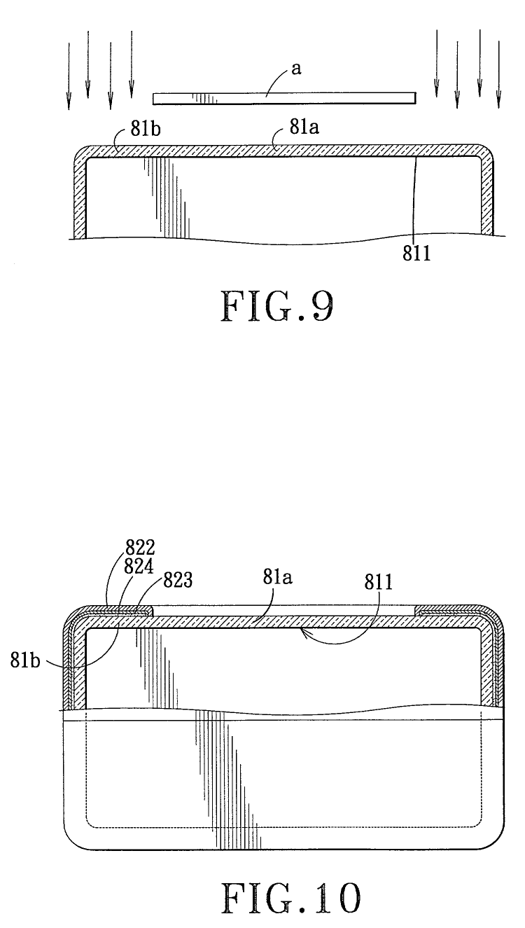

In order to provide the transparent display part 81a and the non-transparent region 81b in the upper plastic case 81, before the sputter deposition of the metal film 812, the transparent plastic substrate 811 is covered with a mask (a) on a portion of the plastic substrate 811, which corresponds to the transparent display part 81a, as shown in FIG. 9. As such, the conductive metal film 812 is prevented from being deposited on and from covering said portion. Said portion finally serves as the transparent display part 81a. According to this embodiment, the transparent display part 81a and the non-transparent region 81b are formed from a one-piece transparent plastic substrate 811, unlike the conventional cell phone housing which is constituted of one piece for a display region and another piece for a non-display region.

Referring to FIG. 10, in the non-transparent region 81b, the outer surface of the plastic substrate 811 is provided with a conductive metal film 824, an adhesive layer 823 and a decorative glossy film 822. The metal films 824 and 822 are formed by sputter-deposition according to the present invention.

While the present invention has been described in connection with what is considered the most practical and preferred embodiment, it is understood that this invention is not limited to the disclosed embodiments but is intended to cover various arrangements included within the spirit and scope of the broadest interpretation so as to encompass all such modifications and equivalent arrangements.

I claim:

1. A plastic article comprises a plastic substrate and a film bonded integrally to a surface of said plastic substrate, said film being formed on said surface via a process which comprises the steps of:
a) bombarding the surface of said plastic substrate with an ionized gas in a vacuum environment to remove contaminants from the surface, to clean the surface and to expose pores clogged by the contaminants in the surface; and
b) depositing said film on the surface cleaned in step a) by sputter deposition.

2. The plastic article as claimed in claim 1, wherein said film is composed of a material selected from the group consisting of pure metals, metal alloys, non-metals, and non-metal chemical compounds.

3. The plastic article as claimed in claim 1, wherein said plastic substrate is made of a plastic material selected from the group consisting of polyacrylate, polycarbonate and acrylonitrile-butadiene-styrene copolymer.

4. A light guide plate for a backlighting device, comprising a transparent plastic substrate, and a reflective metal film bonded intimately to said plastic substrate, said reflective metal film being formed on said plastic substrate by a process which comprises the steps of:
a) bombarding the surface of the transparent plastic substrate with an ionized gas in a vacuum environment to remove contaminants from the surface, to clean the surface, and to expose pores clogged by the contaminants in the surface; and
b) providing said metal film on said surface cleaned in step a) by sputter deposition.

5. The light guide plate as claimed in claim 4, wherein said plastic substrate is polyacrylate.

6. The light guide plate as claimed in claim 5, wherein said metal film comprises a metal selected from a group consisting of aluminum, aluminum alloys, copper, silver alloys and Al₂O₃.

7. A housing for an electronic device which comprises a plastic case, and at least one film bonded intimately to a surface of said plastic case, said film being formed on said surface by a process which comprises the steps of:
a) providing a plastic substrate which is formed as said plastic case;
b) bombarding a surface of said plastic substrate with an ionized gas in a vacuum environment to remove contaminants from the surface, to clean the surface, and to expose pores clogged by the contaminants in the surface; and
c) providing said film on said surface cleaned in step a) by sputter deposition.

8. The housing as claimed in claim 7, wherein said plastic case comprises a material selected from the group consisting of polycarbonate and acrylonitrile-butadiene-styrene copolymer.

9. The housing as claimed in claim 8, wherein said film is formed of a material selected from the group consisting Al, Cr, Cu, Ti, Nicr, Ni, (Al₂O₃+Pb), (Al₂O₃+Sb) (Al₂O₃+As), TiO₂, Al₂O₃, TiB₂, and SiO₂.

10. The housing as claimed in claim 9, wherein said plastic case has a transparent display part and a non-transparent region, and said process further comprises using a one-piece transparent plastic material to form said plastic substrate in step (a) so that said plastic substrate is transparent, and providing said transparent display part and said non-transparent region by covering a portion of said transparent plastic substrate with a mask before step (c) so as to prevent said film from being deposited on said portion, whereby said portion forms said transparent display part, and the remaining portion of said transparent plastic substrate, which is not covered by said mask, forms said non-transparent region.

11. A housing as claimed in claim 10, wherein said film is a conductive metal film capable of providing electromagnetic shielding.

12. A housing as claimed in claim 10, wherein said film is a decorative film.

13. A housing as claimed in claim 10, wherein said plastic case further includes another film provided on said film via sputter deposition, one of said film and said another film being a conductive metal film capable of providing electromagnetic shielding, the other one of said film and said another film being a decorative film.

14. A housing as claimed claim 13, wherein said plastic case further includes an adhesive layer disposed between said film and said another film.
